(19) United States
(12) Patent Application Publication
(10) Pub. No.: US 2026/0112815 A1
(43) Pub. Date: Apr. 23, 2026

(54) PARAMETRIC MATCHING METHODS FOR BROADBAND, HIGH SENSITIVITY RECEPTION WITH ELECTRICALLY SMALL ANTENNAS

(71) Applicant: THE REGENTS OF THE UNIVERSITY OF CALIFORNIA, Oakland, CA (US)

(72) Inventor: Yuanxun Wang, Los Angeles, CA (US)

(73) Assignee: THE REGENTS OF THE UNIVERSITY OF CALIFORNIA, Oakland, CA (US)

(21) Appl. No.: 19/384,311

(22) Filed: Nov. 10, 2025

Related U.S. Application Data
(63) Continuation of application No. PCT/US2024/029659, filed on May 16, 2024.
(60) Provisional application No. 63/502,711, filed on May 17, 2023.

(51) Int. Cl. H01Q 9/24; H03F 1/56; H03F 7/00

(52) U.S. Cl. CPC H01Q 9/24; H03F 1/56; H03F 7/00; H03F 2200/222; H03F 2200/294

(57) ABSTRACT

A matching technique for receivers with ESA so that the receiver can achieve low noise performance over a broad bandwidth. An electrically small dipole is matched directly to a parametric amplifier, without using any inductors. The parametric amplifier operates in a time-varying fashion, driven by a higher RF frequency pump, and exhibits a high impedance, time-varying capacitive load to the ESA. Therefore, the low frequency voltage output from the ESA is detected at the input of the parametric amplifier, being amplified and upconverted to the proximity of the pump frequency at the output with minimum contamination of noise in this process.

### CROSS-REFERENCE TO RELATED APPLICATIONS

This application claims priority to, and is a 35 U.S.C. § 111(a) continuation of, PCT international application number PCT/US2024/029659 filed on May 16, 2024, incorporated herein by reference in its entirety, which claims priority to, and the benefit of, U.S. provisional patent application Ser. No. 63/502,711 filed on May 17, 2023, incorporated herein by reference in its entirety. Priority is claimed to each of the foregoing applications.

The above-referenced PCT international application was published as PCT International Publication No. WO 2024/238771 A1 on Nov. 21, 2024, which publication is incorporated herein by reference in its entirety.

### STATEMENT REGARDING FEDERALLY SPONSORED RESEARCH OR DEVELOPMENT

Not Applicable

### NOTICE OF MATERIAL SUBJECT TO COPYRIGHT PROTECTION

A portion of the material in this patent document may be subject to copyright protection under the copyright laws of the United States and of other countries. The owner of the copyright rights has no objection to the facsimile reproduction by anyone of the patent document or the patent disclosure, as it appears in the United States Patent and Trademark Office publicly available file or records, but otherwise reserves all copyright rights whatsoever. The copyright owner does not hereby waive any of its rights to have this patent document maintained in secrecy, including without limitation its rights pursuant to 37 C.F.R. § 1.14.

### BACKGROUND

### 1. Technical Field

The technology of this disclosure pertains generally to matching circuits for electrically small antennas, and more particularly to direct active matching which provides optimized signal to noise ratio of the receiver with the antenna instead of a conjugate impedance match.

### 2. Background Discussion

Impedance matching on electrically small antennas (ESAs) is difficult and subject to low efficiency and/or bandwidth. Since radiation resistances of ESAs are often very small, such as having sub-Ohm values, and high radiation Q, the use of conventional conjugate matching strategies for transforming the extremely low radiation resistances lead to significant losses and bandwidth restrictions.

Accordingly, a need exists for a structure and method to achieve improved matching of ESAs. The present disclosure fulfills that need and provides additional benefits over existing matching systems.

### BRIEF SUMMARY

The technology of the present disclosure provides improvements in utilizing parametric amplification of nonlinear electron spin precessions in ferrite to allow detection of an extremely weak magnetic field with a small form factor antenna (or sensor) over a very broad band with almost no frequency dependence. In contrast to recent directions in the industry, the technology disclosed requires the use of magnetic material. However, the disclosed technology provides numerous benefits, including capability of achieving the desired broadband low noise performance at High Frequency (HF), Very High Frequency (VHF), or even Ultra High Frequency (UHF) bands.

Further aspects of the technology described herein will be brought out in the following portions of the specification, wherein the detailed description is for the purpose of fully disclosing preferred embodiments of the technology without placing limitations thereon.

### BRIEF DESCRIPTION OF THE DRAWINGS

The technology described herein will be more fully understood by reference to the following drawings which are for illustrative purposes only:

FIG. 1A and FIG. 1B are circuit models of electrically small dipole and small loop antennas.

FIG. 2A through FIG. 2C show geometry for a bowtie dipole, and circuit models from full-wave simulation S-parameters.

FIG. 3A and FIG. 3B are graphs of magnitude and phase of the S-parameters for the circuit model of FIG. 2A through FIG. 2C.

FIG. 4A and FIG. 4B are block diagrams of a conventional receiver design using a matching circuit to match the Electrically Small Antenna (ESA) to a source impedance at the Low Noise Amplifier (LNA).

FIG. 5A and FIG. 5B are graphs of Gain and Noise figures for different matching conditions.

FIG. 6 is a circuit diagram of Direct Active Matching (DAM) for an electrically small bowtie antenna with parametric amplifiers utilizing a balanced diode bridge, according to at least one embodiment of the present disclosure.

FIG. 7 is a schematic of a parametric amplifier having an arbitrary source and load for theoretical analyses according to at least one embodiment of the present disclosure.

FIG. 8 is a schematic of the DAM circuit with the parametric amplifier designed for the electrically small bowtie as shown in FIG. 2A, according to at least one embodiment of the present disclosure.

FIG. 9A and FIG. 9B are graphs of simulated results for the parametric DAM technique comparing to the theoretical prediction and the simulated result with transistor DAM in regard to both gain and noise figure.

### DETAILED DESCRIPTION

Electrically small antennas (ESAs) with their maximum dimensions less than one-tenth of a wavelength are well known to suffer small efficiency bandwidth products in their impedance match. This conclusion is drawn from two fundamental limits in electromagnetics. The first limit is Harrington-Chu's limit that defines the lower bound of the radiation quality factor of an ESA and the second limit is the Bode-Fano limit in impedance matching theory which indicated the efficiency bandwidth product in impedance match must be inversely proportional to the quality factor of the load, which is the radiation quality factor for an antenna. Based on this understanding, a wider bandwidth may be yielded for lossy antennas or with a lossy matching network at the price of the degraded efficiency of the ESA.

Traditionally the antenna matching to the receiver is carried out as two separate tasks. A common interface impedance, e.g., 50 Ohm, is often set at first so that the antenna output is conjugately matched to this common impedance through a matching network. On the other hand, the input of a low noise amplifier (LNA) as the first stage of the receiver is also designed to match to this common impedance, although the matching may not be exactly conjugate as oftentimes a minimum noise figure of the LNA is yielded at a condition slightly off from the conjugate match at the input. This strategy guarantees the best signal-to-noise ratio (SNR) of the receiver system if the signal is within the matched bandwidth and when loss is not present in the matching network as the maximum amount of signal power is delivered to the LNA and consequently the impact of the noise added by the LNA can be minimized.

For ESAs, their radiation resistances are often very small, and with sub-Ohm values. In addition to their high radiation Q, transforming the extremely low radiation resistances of the ESAs to 50 Ohm will inevitably incur great loss and narrow bandwidth in the impedance matching network. The same issues may be applied for the impedance transformation network between the LNA and the common impedance interface, particularly when low quality factor inductors are used as part of the matching network. The loss in the matching network will elevate the noise level in the receiver and reduce its sensitivity. The SNR benefit of maximizing the signal power delivered to the LNA may no longer be obtained. It has thus been shown that ESAs directly connected to a LNA without going through a conjugate impedance match may exhibit a better SNR in the receiver, especially when considering a wide operating bandwidth.

On the other hand, to achieve the desired SNR or sensitivity performance of the receiver, conjugate match may not be needed at all if the first stage of the receiver is close to noiseless and with positive gain. When the thermal noise of the environment is dominant in the antenna, a lossless mismatch of the antenna to the LNA reduces the delivered signal power to the LNA as well as the noise power. For example, specialized field sensors such as Superconducting Quantum Interference Device (SQUID) or Spin-Exchange Relaxation-Free (SERF) devices have been used to detect extremely weak low frequency magnetic fields over a broad bandwidth, and provide significantly improved performance over what a conventional antenna can offer, as it is no longer necessary to maximize the signal power delivered to combat the noise added by the sensor. Recently, a solid-state magnetic field sensing technique called RF precession modulation was proposed. With such sensors, very weak magnetic fields can be detected with a small form factor sensor as the field to be detected modulates the electron spin precession at resonance and this is parametrically amplified by the material before it is finally detected by the inductive coil.

Integrating parametric amplifiers into antennas has also been attempted, however, the amplification is still resonance-based and only operates over a narrow band. In fact, the studies of individual examples of these designs provided no sufficient evidence suggesting that the efficiency bandwidth product of an electrically small antenna can be overcome through integration of a parametric amplifier in the conventional manner.

### 2. Circuit Models of ESAs

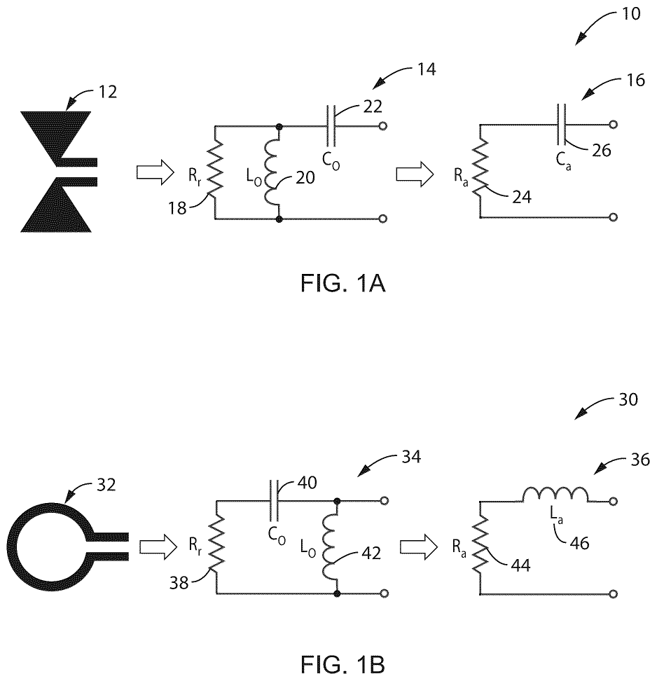

FIG. 1A and FIG. 1B illustrate equivalent circuit models 10 and 30 comparing dipole antenna and an electrical loop antenna. In FIG. 1A the electrically small dipole antenna 12 is represented by an equivalent circuit model 14, having resistance 18 and inductance 20 in parallel and coupled through a series capacitance 22. The model assumes TM₁ mode as in the discussions by Chu. Also is shown model 16 having a simplified series resistor 24 and capacitor 26 as is often quoted in the textbooks.

In FIG. 1B is shown an electrically small loop 32 represented by an equivalent circuit model 34 assuming TE₁ mode as in the Chu's discussion having resistance 38 in series with capacitance 40, and a shunt inductance 42. A simplified series resistor inductor model 36 is also shown as is often quoted in textbooks, having a resistance 44 in series with inductance 46.

The properties of electrically small antennas have been well studied in Harrington and Chu's work in the 1940s. As the goal of this effort is to achieve broadband low noise performance of the receiver with ESAs, through usage of active and time-varying matching techniques, one must understand the circuit nature of the ESAs so that co-design of the antenna with front-end is possible. A series resistor capacitor model for electrically small dipole and a series resistor inductor model for electrically small loops are often quoted in textbooks. Yet more accurate circuit models that represents the broadband behavior of ESAs were presented in Chu's original discussions where the famous Chu's limit was derived. Chu's circuit models for the lowest order electric dipole (TM₁) and magnetic dipole mode (TE₁) are shown in circuits 14 and 34 of FIG. 1A and FIG. 1B, respectively, which were intended to represent the near field energy characteristics of both modes outside a sphere of a radius that encloses the antenna. The following values of the inductance and capacitance are normalized according to its radiation resistance Rᵣ as specified by,

$$\{ \begin{matrix}{L}_{0} = \frac{a}{c} \\ {C}_{0} = \frac{a}{c}\end{matrix} \qquad ( 1 )$$

where c is the free space speed of light. With simple modifications to the expressions in Eq. (1), the circuit models have been found to be accurate representations of broadband behaviors of electrically small dipoles or loops from DC up to the first resonance frequencies of the antennas. Under the high-Q assumptions, Chu's circuit models can be simplified to the ones with only two components as shown in models 16 and 36, of FIG. 1A and FIG. 1B, respectively, through the following relation,

$$\{ \begin{matrix}{R}_{a} \approx \frac{{( ω {L}_{0} )}^{2}}{{R}_{r}} , {C}_{a} \approx {C}_{0} - \frac{1}{{ω}^{2} {L}_{0}} \approx {C}_{0} ( electrically small dipole ) \\ {R}_{a} \approx {ω}^{4} {L}_{0}^{2} {C}_{0}^{2} {R}_{r} , {L}_{a} \approx {L}_{0} ( elec t rically small loop )\end{matrix} \qquad ( 2 )$$

The radiation quality factors are given by,

$$\{ \begin{matrix}{Q}_{a} = \frac{1}{ω {C}_{a} {R}_{a}} \approx \frac{{R}_{r}}{{ω}^{3} {L}_{0}^{2} {C}_{0}} ( electrically small dipole ) \\ {Q}_{a} = \frac{ω {L}_{0}}{{ω}^{4} {L}_{0}^{2} {C}_{0}^{2} {R}_{r}} \approx \frac{1}{{ω}^{3} {L}_{0} {C}_{0}^{2} {R}_{r}} ( electrically small loop )\end{matrix} \qquad ( 3 )$$

Both radiation quality factors are inversely proportional to the cubic order of the operating frequency, which is as stated in Chu's limit. It is also evident that the radiation resistance of an electrically small loop is significantly smaller than for an electrically small dipole at a lower frequency, for example because of the very small ka values. A loop of multiple turns is often used to boost radiation resistance, yet the Ohmic resistance of the loop itself often cannot be ignored, which adds noise to the antenna and sets its sensitivity limit. On the other hand, electrically small dipoles operate in the manner of an electric field sensor. They incur a minimum of current and are less susceptible to Ohmic resistance.

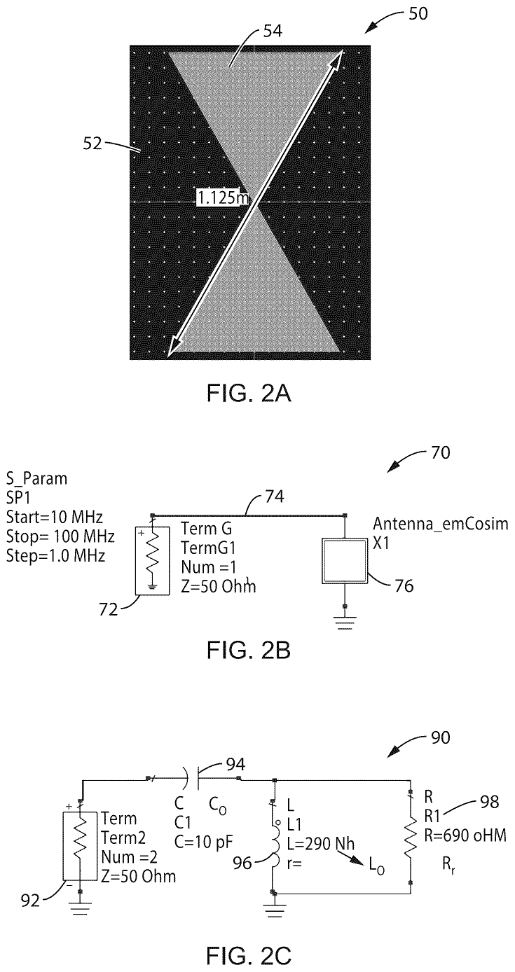

FIG. 2A through FIG. 2C illustrates geometry of an electrically small planar bowtie dipole 50, as well as the Chu's circuit model extractions 70, 90, from a full-wave simulation of S-parameters.

The present disclosure focuses on electrically small dipoles and applying active and time-varying matching to enable broadband, low noise operation. An electrically small planar bowtie dipole 50 is designed with a maximum dimension of 1.125 m which corresponds to ka=½ at 42.5 MHz. In the model 70 of FIG. 2B is shown antenna 76 coupled to a terminal 72 having impedance of 50 ohms. The antenna was simulated in Keysight ADS Momentum, and its input impedance is used to fit to a Chu's TM₁ mode circuit model as shown 90 in FIG. 2C which yielded component values of 98 R_{f}=690 Ohm, 96 L₀=290 nH and 94 C₀=10 pF for the terminal impedance of 50 ohms. The radiation quality factor obtained with Eq. (2) is about 4 times that of Chu's limit and is very close to the Gustafsson's limit for electrically small planar antennas.

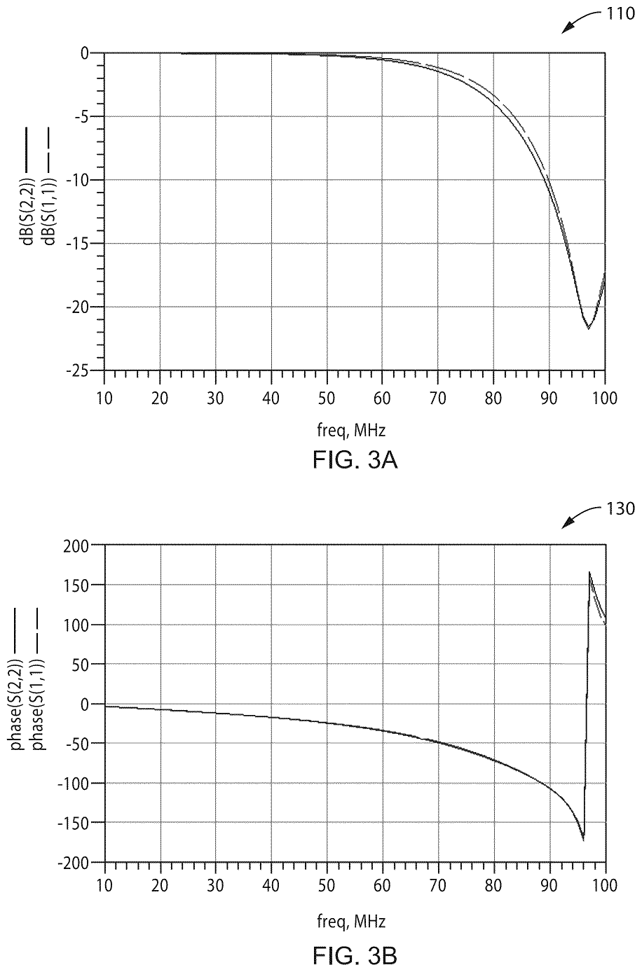

FIG. 3A and FIG. 3B illustrate 110, 130 the fitting of both the magnitude and phase of the S parameters between the full-wave simulation results and the circuit prediction, which can be seen to be a very close fit from 10 MHz to 100 MHz with maximum amplitude deviation of less than 0.5 dB and phase deviation of less than 5 degrees. Simulation also shows that the Ohmic resistance of the bowtie is negligible. Next, we will use this extracted circuit model to optimize the noise performance of the receiver when such an antenna is integrated.

### 3. Noise Performance Characterization for Receivers Including ESA

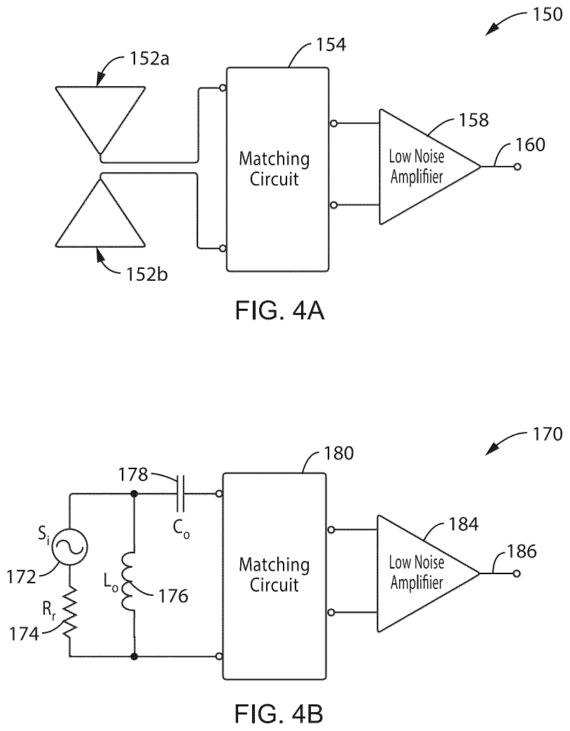

FIG. 4A and FIG. 4B illustrate a comparison between a conventional receiver design 150 and a receiver design 170 as shown according to the present disclosure.

In FIG. 4A is shown a conventional receiver design using a matching circuit to match the ESA to a source impedance at the LNA that minimizes the noise figure of the LNA. In FIG. 4B it is shown that in order to minimize the noise of the entire receiver, one must include the Chu equivalent circuit of ESA as part of the system and optimize the noise figure defined from the radiation resistance to the output of the amplifier.

In FIG. 4A antenna 152a, 152b is coupled to a matching circuit 154, coupled to an LNA 158 with output 160 of a conventional receiver design is used: (1) to perform antenna matching (e.g., match the ESA to a common reference impedance, such as 50 Ohm); and (2) to perform noise matching of the LNA, (e.g., transform the 50 Ohm impedance to a source impedance at the input of the low noise amplifier that minimizes the amplifier noise figure.

This matching strategy leads toward obtaining optimal noise figure performance of the receiver with two constraints. The first constraint is that such matching is only possible over a narrow frequency band for ESAs that are of high radiation Q, as indicated by the Bode-Fano limit. The second constraint is that optimum noise matching ignores the loss of the matching circuits, which would otherwise add noise and degrade the system noise figure and invalidate the assertion of the optimum noise figure.

To optimize the receiver noise performance toward its true minimum, or toward broadband operations, the ESA was incorporated as part of the circuit and the noise figure analyzed from the wave port of the antenna to the output of the LNA. This can be performed by replacing the ESA with Chu's equivalent circuit and treating the radiation resistance as the source resistance for noise figure calculation.

In FIG. 4B is shown the receiver in which the radiation resistance is treated as the source resistance and replacing the ESA with the equivalent circuit of Chu, showing Sᵢ 172, Rᵣ 174, L₀ 176, C₀ 178, into matching circuit 180 shown coupled to LNA 184 with output 186. In this way, the receiver includes the impact of the loss of the antenna and the matching circuit and any mismatch on SNR of the reception into this system noise figure.

By way of example and not limitation, to evaluate the noise performance of a typical receiver with ESA, the LNA was designed with high performance components, such as Cree's 0.25 um GaN HEMT device CGHV1J006D which is a bare chip that can operate as an amplifier at up to 18 GHz. Three cases were studied with circuit simulations using Keysight ADS. In the first case, a resonant matching circuit was designed which resonates the series capacitance in the antenna model with a series inductor and resonates the shunt inductance in the antenna model with a shunt capacitance, both at 30 MHz. The inductor used in the matching circuit was assumed to be ideal. In the second case, the same resonant matching was applied with the exception that the inductor is assumed to have a limited Q of 100 at 30 MHz. Such an inductor would require special techniques to construct, as commercial off the shelf (COTS) inductors at this frequency have typical Qs of around 20 to 30. In the third case, the ESA is connected directly to the LNA without going through any matching circuit, which is what is termed in this disclosure as Direct Active Matching (DAM).

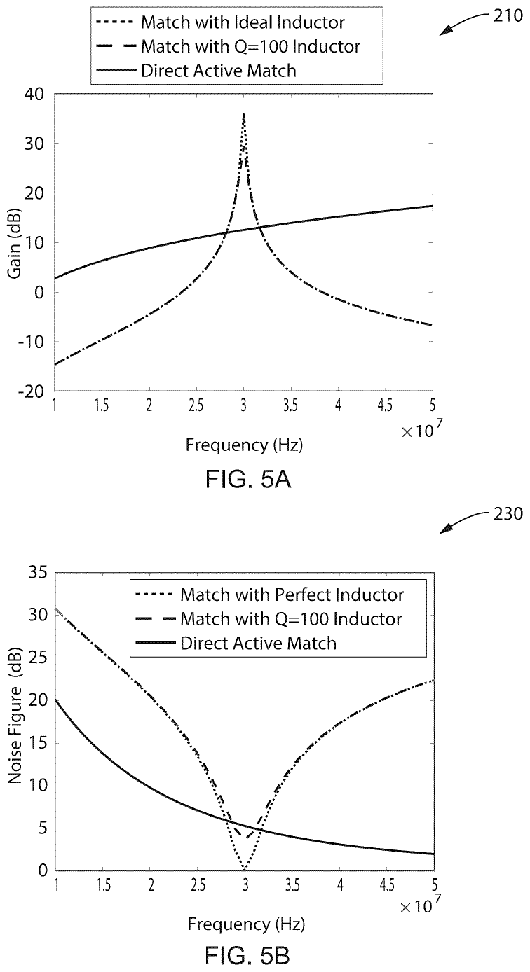

FIG. 5A and FIG. 5B are graphs of simulated transducer Gain and Noise figures for different matching conditions. In FIG. 5A is shown 210 simulated transducer gain while in FIG. 5B is shown 230 the simulated noise figure, of the receiver with ESA for different matching conditions. By way of example and not limitation, in this example, a Cree 0.25 um GaN HEMT device CGHV1J006D was used to create a low-noise amplifier after the antenna for all cases.

From FIG. 5A it is evident that resonant matching with ideal components achieves the highest gain of around 36 dB and from FIG. 5B the lowest noise figure of approximately 0.1 dB at 30 MHz. A slight gain drop of 6 dB is observed when the matching inductor has a Q of 100 and the lowest noise figure now becomes 3.7 dB. The gain and noise figure of both resonant matching cases degrade quickly once the operating frequency deviates from resonance. The DAM scheme exhibits a significantly lower gain at 30 MHz comparing to the resonant matching cases due to the reflection between the ESA and the LNA input. However, a relatively flat gain curve can still be yielded from 10 MHz to 50 MHz. In the noise figure plot, DAM scheme displays a flat noise figure behavior, and it is 5 dB at 30 MHz, only slightly higher than the resonant matching case with a Q=100 inductor. The noise figure is significantly lower than both resonant matching cases once the operating frequency moves away from 30 MHz by more than 2 MHz, which implies DAM may offer superior performance for broadband applications even with the ESA on board. Since no matching circuit is simulated performance levels are more practically achievable, as is indicated in these graphs.

### 4. Electrically Small Antennas Matched With Parametric Amplifiers

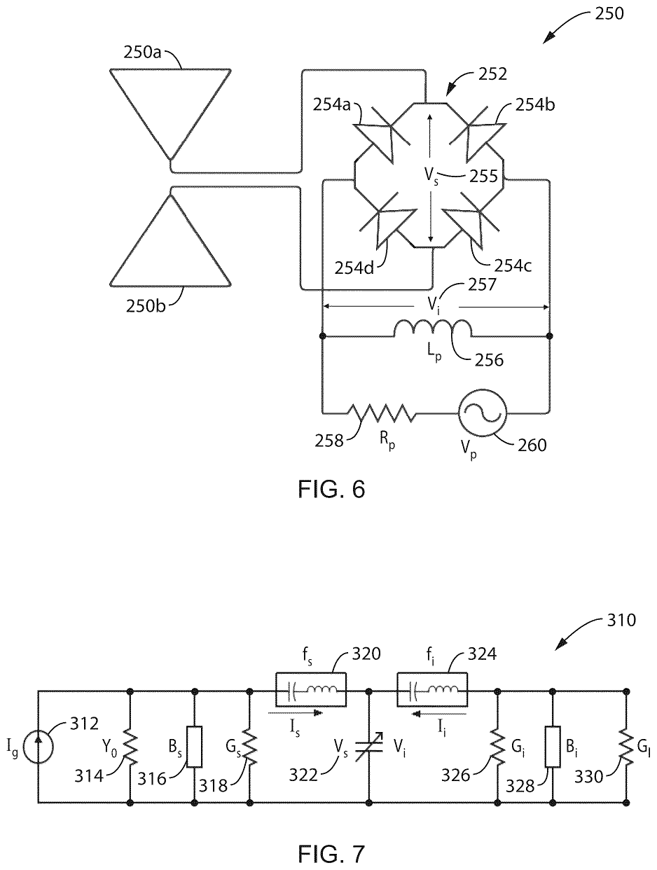

FIG. 6 illustrates an example embodiment 250, showing a circuit diagram of Direct Active Matching (DAM) for an electrically small bowtie antenna with parametric amplifiers utilizing a balanced diode bridge.

DAM of ESA with transistors offers a broader band performance yet the noise figure is still high which is around 5 dB for a High Frequency (HF) ESA with a dimension of ka=⅓. One goal of this effort is achieving multi-octave operation with a noise figure of below 3 dB, with ka below ½ throughout the entire band. It will be shown below that this is achievable with a novel DAM strategy using parametric amplifiers.

Parametric amplifiers are based on nonlinear reactive devices such as varactor diodes. They exhibit time-varying reactance under the excitation of a high frequency pump so that the incoming signal at a lower frequency is amplified or upconverted with a positive gain. They were extensively studied in the 1950s, yet there has been a recent surge of interest on using their time-varying and low-noise property for novel applications, such as nonmagnetic nonreciprocal devices, Q-enhanced filters and low-noise mixers and downconverters. Integrating parametric amplifiers into antennas has also been attempted; however, the amplification is still resonance based and thus operates only over a narrow band. A recent work utilizing parametric amplification of nonlinear electron spin precessions in ferrite allows detection of extremely weak magnetic field with a small form factor sensor where the field is amplified before it is upconverted and detected by a coil. One distinctive feature of that recent work is that the increased sensitivity is achieved over a very broad band with almost no frequency dependence.

The parametric amplifier in FIG. 6 is shown with a balanced varactor diode bridge having double sideband idler outputs. A bowtie antenna 250a, 250b is shown coupled to first opposing set of input on a diode bridge 252, shown with diodes 254a through 254d. Coupled to the second opposing set of inputs on a diode bridge is a source Vₚ 260 in series with resistance 258 and shunted by inductance Lₚ 256, across which is seen voltage Vᵢ. The signal Vs 255 is shown across the first set of inputs to the diode bridge (same set as antenna are coupled to) while the pump is added from the second set of input of the diode bridge. The electrically small bowtie is directly connected to the diode bridge, without going through any impedance matching or transformation circuit.

The idler signals Vᵢ 257 are extracted at the pump port and can be separated from the pump by using a circulator or a diplexer. Compared with other existing circuits, which use a resonant matching network and diplexers to separate the different tones (signal, idler and pump), the balanced diode bridge allows the signal path to be isolated from the pump and idler paths so that the ESA only sees the diode capacitance. This is critical to the noise performance of the receiver as any matching inductors or filters at the signal path may add additional noise to the system. The pump frequency is selected to be sufficiently high in relation to the signal so that the two idler sidebands fall within the bandwidth of the resonance of the pump loop.

Matching inductors and impedance transformation circuits can be added at the pump and idler port to assure a high energy delivery efficiency and the impact of these circuits to the noise performance is minimum as the signal is already amplified at the idler outputs. The double sideband idler parametric amplifier offers improved gain over the parametric upconverter, and lower noise compared to the negative impedance parametric amplifier.

The complete theory for DAM with such a parametric amplifier is presented as follows.

FIG. 7 illustrates the simplified schematic 310 of an example embodiment of the parametric circuit with arbitrary source I_{g} 312 and load G_{I} 330 for the derivation of the theory behind the disclosed operation. Y₀ 314 is the source conductance of the antenna, Bₛ 316 is the source susceptance and Gₛ 318 is the equivalent shunt conductance on the signal side which represents the loss of the diode reflected onto the signal side. G_{I} 326 is the load conductance which represents the equivalent shunt conductance of the diode on the idler side. Bᵢ is the susceptance in the idler path. Blocks fₛ 320 and fᵢ 322 are filters. Voltages and currents, IS The cross-frequency admittance matrix is thus given by,

$$( \begin{matrix}{I}_{s} \\ {I}_{i ‐}^{*} \\ {I}_{i +}\end{matrix} ) = ( \begin{matrix}{Y}_{11} & {Y}_{12} & {Y}_{13} \\ {Y}_{21} & {Y}_{22} & {Y}_{23} \\ {Y}_{31} & {Y}_{32} & {Y}_{33}\end{matrix} ) ( \begin{matrix}{V}_{s} \\ {V}_{i ‐}^{*} \\ {V}_{i +}\end{matrix} ) = ( \begin{matrix}j {ω}_{s} {C}_{0} & j {ω}_{s} γ {C}_{0} & j {ω}_{s} γ {C}_{0} \\ - j {ω}_{i -} γ {C}_{0} & - j {ω}_{i -} {C}_{0} & 0 \\ j {ω}_{ι +} γ {C}_{0} & 0 & j {ω}_{i +} γ {C}_{0}\end{matrix} ) ( \begin{matrix}{V}_{s} \\ {V}_{i -}^{*} \\ {V}_{i +}\end{matrix} ) \qquad ( 4 )$$

where Vs 322, Is, Vᵢ−, Iᵢ−, Vᵢ₊ and Iᵢ₊ are voltages and currents for the signal, the lower sideband of idler and the upper sideband of the idler, γ is the capacitance modulation index which can be approximately derived by measuring the slope of the capacitance versus voltage relation, for example,

$$γ = \frac{1}{2} \frac{{C}_{max} - {C}_{min}}{{C}_{max} + {C}_{min}} \qquad ( 5 )$$

where Cₘₐₓ and Cₘᵢₙ are respectively the highest and lowest capacitance value under the influence of the pump voltage. The transducer gain from the signal to the idler port is thus,

$${G}_{t} = \frac{4 {Y}_{0} {G}_{1} {V}_{i}^{2}}{{\vert {I}_{g} \vert}^{2}} \qquad ( 6 )$$

On the idler port, both sidebands have the termination condition that defines

$$\{ \begin{matrix}{I}_{i -}^{*} = - ( {G}_{i} + {G}_{1} - {jB}_{i} ) {V}_{i -}^{*} \\ {I}_{i +} = - ( {G}_{i} + {G}_{1} + {jB}_{i} ) {V}_{i +}\end{matrix} \qquad ( 7 )$$

Substituting (7) into the last two equations of (4) yields,

$$\{ \begin{matrix}{V}_{i -}^{*} = \frac{j {ω}_{i -} γ {C}_{0}}{{G}_{i} + {G}_{1} - j {B}_{i} - j {ω}_{i -} {C}_{0}} {V}_{s} \\ {V}_{i +} = - \frac{j {ω}_{i +} γ {C}_{0}}{{G}_{i} + {G}_{1} + j {B}_{i} + j {ω}_{i +} {C}_{0}} {V}_{s}\end{matrix} \qquad ( 8 )$$

With a narrow band assumption at the upconverted frequencies, both idlers are resonant so that the reactance in the denominators disappear, the following relation approximately holds,

$${V}_{i -}^{*} + {V}_{i +} = 0 \qquad ( 9 )$$

This leads to a simplification of the first equation in (4), which becomes,

$${I}_{s} = j {ω}_{s} {C}_{0} {V}_{s} + j {ω}_{s} γ {C}_{0} ( {V}_{i -}^{*} + {V}_{i +} ) = j {ω}_{s} {C}_{0} {V}_{s} \qquad ( 10 )$$

The input current is thus yielded as

$$\vert {I}_{g} \vert = \vert {I}_{s} + ( {Y}_{0} + {G}_{s} + {jB}_{s} ) {V}_{s} \vert = \vert ( {Y}_{0} + {G}_{s} + {jB}_{s} + j {ω}_{s} {C}_{0} ) \frac{{G}_{i} + {G}_{1}}{j {ω}_{i} γ {C}_{0} {V}_{i}} \vert \qquad ( 11 )$$

Substituting it into Eq. (5) leads to the transducer gain expression,

$${G}_{T} = \frac{4 {Y}_{0} {G}_{1} {γ}^{2} {ω}_{i}^{2} {C}_{0}^{2}}{{\vert {Y}_{0} + {G}_{s} + j {B}_{s} + j {ω}_{s} {C}_{0} \vert}^{2} {( {G}_{i} + {G}_{1} )}^{2}} . \qquad ( 12 )$$

When the parametric amplifier is directly connected to an electrically small dipole represented by its Chu's equivalence and next the series RC approximation, one can define the radiation quality factor of the antenna and the intrinsic quality factor of the varactor diode at the original signal frequency as,

$${Q}_{a} = \frac{{B}_{s}}{{Y}_{0}} , {Q}_{d} = \frac{{ω}_{s} {C}_{0}}{{G}_{s}} \qquad ( 13 )$$

The idler output assumes a conjugate match with Gᵢ=G_{I}, the transducer gain then becomes,

$${G}_{T} = \frac{{Y}_{0} {G}_{s}}{{( {Q}_{a} {Y}_{0} + {Q}_{d} {G}_{s} )}^{2}} \frac{{ω}_{i} {C}_{0}}{{G}_{s}} \frac{{ω}_{i} {C}_{0}}{{G}_{i}} {γ}^{2} \qquad ( 14 )$$

It should be noted that the varactor diode quality factor is inversely proportional to its operating frequency, at the idler frequency, it satisfies

$${Q}_{d , {ω}_{i}} = \frac{{ω}_{i} {C}_{0}}{{G}_{i}} = \frac{{ω}_{s}}{{ω}_{i}} {Q}_{d} .$$

The transducer equation (14) thus becomes,

$${G}_{T} = \frac{{Y}_{0} {G}_{s}}{{( {Q}_{a} {Y}_{0} + {Q}_{d} {G}_{s} )}^{2}} {Q}_{d}^{2} {γ}^{2} \qquad ( 15 )$$

One can prove that the transducer gain is maximized when the following holds,

$${Q}_{a} {Y}_{0} = {Q}_{d} {G}_{s} \qquad ( 16 )$$

This optimum matching condition gives,

$${ω}_{s} {C}_{a} = {ω}_{s} {C}_{0} or {C}_{a} = {C}_{0} \qquad ( 17 )$$

Substituting Eq. (16) into Eq. (15) and considering both single side band and double side band cases, the maximized transducer gain is thus,

$${G}_{T , max} = \frac{1}{4} \frac{{Q}_{d}}{{Q}_{a}} {γ}^{2} ( SSB ) or {G}_{T , max} = \frac{1}{2} \frac{{Q}_{d}}{{Q}_{a}} {γ}^{2} ( DSB ) \qquad ( 18 )$$

It should be appreciated that the transducer gain for double sideband increases by a factor of two from that of a single sideband as both idler tones can be combined in power through a coherent down-converter.

To derive the noise figure expression, current sources at both signal and idler frequencies will be used to represent thermal noise. The noise power delivered to the load G_{I} due to the thermal source at the signal frequency fₛ is,

$${N}_{s} = {G}_{T} {i}_{n s}^{2} / 4 {Y}_{0} \qquad ( 19 )$$

Similarly, for the noise source at the idler frequency fᵢ is,

$${N}_{i} = \frac{{i}_{n i}^{2}}{{( {G}_{i} + {G}_{1} )}^{2}} {G}_{1} \qquad ( 20 )$$

The thermal noise currents at fₛ and fᵢ are,

$${i}_{n s}^{2} = 4 K {T}_{0} B ( {Y}_{0} + {G}_{s} ) and {i}_{n i}^{2} = 4 K {T}_{0} B ( {G}_{i} ) . \qquad ( 21 )$$

The total noise power is the sum of Nₛ and Nᵢ as,

$${N}_{o} = {N}_{s} + {N}_{i} . \qquad ( 22 )$$

The noise figure then is,

$$F = \frac{{N}_{o}}{{G}_{T} k {T}_{0} B} = \frac{1}{k {T}_{0} B} ( \frac{{i}_{n s}^{2}}{4 {Y}_{o}} + \frac{1}{{G}_{T}} \frac{{i}_{n i}^{2}}{{( {G}_{i} + {G}_{1} )}^{2}} {G}_{1} ) . \qquad ( 23 )$$

This expression can be further simplified to,

$${F}_{N} = 1 + \frac{{G}_{s}}{{Y}_{0}} + \frac{1}{{G}_{T}} \frac{4 {G}_{i} {G}_{1}}{{( {G}_{i} + {G}_{1} )}^{2}} \qquad ( 24 )$$

Under the maximum gain condition, the noise figure thus becomes,

$${F}_{N} = 1 + \frac{{G}_{s}}{{Y}_{0}} + \frac{1}{{G}_{T}} = 1 + \frac{{Q}_{a}}{{Q}_{d}} ( 1 + \frac{2}{{γ}^{2}} ) \qquad ( 25 )$$

Since γ has a maximum value of 0.5, it is evident from Eq. (18) and Eq. (25) that the diode quality factor needs to be at least one order of magnitude higher than the radiation quality factor of the ESA in order to realize positive gain and low Noise Figure (e.g., NF less than 3 dB). Some of the GaAs varactor diodes that were utilized are from Global Communications Semiconductor® (GCS) 1 um InGaAs HBT process. The capacitance modulation index γ is approximately 0.3 and its cutoff frequency is approximately 140 GHz. At 30 MHz, the diode Q is 4300 and the radiation Q of the electrically small bowtie dipole with a dimension of ka=⅓ at 30 MHz is approximately 120. Therefore, a low noise performance is expected with DAM through such varactor diodes.

Theoretically, Field Effect Transistors (FET) can be used in a similar manner to match an ESA with its high gate input impedance. In a real FET device, however, the Miller capacitance of the transistor allows the drain source conductance coupled back to the input and increases the noise level under this severely mismatched case. The stability of transistor amplifiers can also become a problem at lower frequency as the gain becomes too high. In contrast, double sideband parametric amplifiers are unconditionally stable as the gain is always a finite value as indicated by Eq. (12).

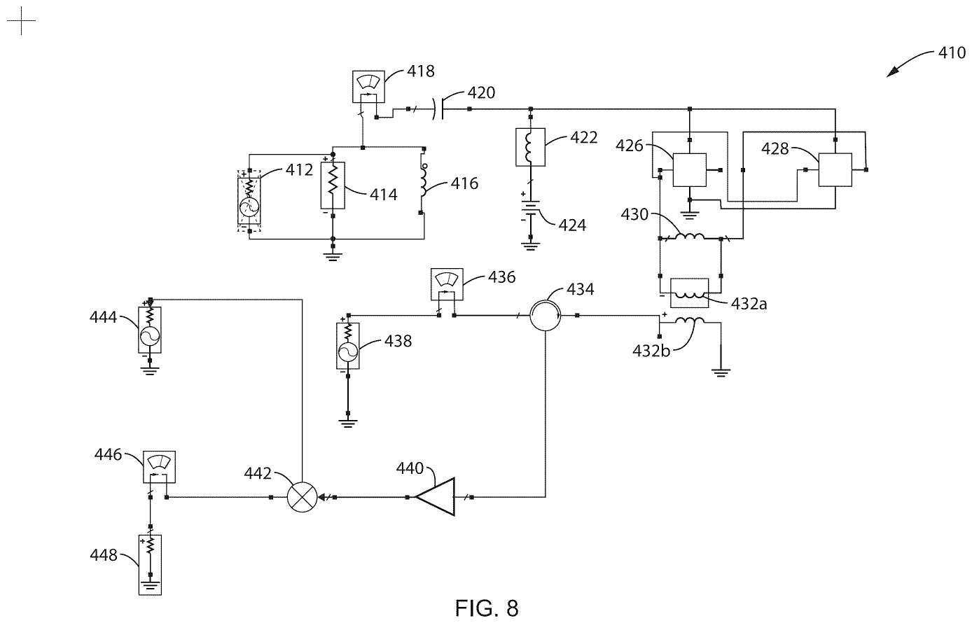

FIG. 8 illustrates an example embodiment 410 of a schematic for the 3D planar electromagnetic (EM) simulator (e.g., Keysight ADS Momentum simulator) of the DAM circuit with the parametric amplifier designed for the electrically small bowtie as shown in FIG. 2A.

By way of example, the matching parametric amplifier was designed in ADS and the theory validated through circuit simulations. The input is Chu's equivalent circuit for the electrically small bowtie designed in FIG. 2A and FIG. 2B, shown with source and series resistance 412, shunt resistance 414 and shunt inductor 416, shown registered by probe 418. It should be noted that probes just provide points at which waveforms are registered in the simulation. Then the signal passes through capacitance 420 and having a DC voltage feed 424 through inductor 422, prior to its input to the diode bridge arrays 426, 428 shown in parallel. Inductor 430 is shown across the output of the bridges to an inductive coupling (transformer) having input side 432a and output 432b which is coupled to circulator 434. One output of the circulator is registered by probe 436 to a port 2 pump source 438. Another output of the circulator is directed to an amplifier 440, whose output is coupled to a mixer 442 which receives input from an oscillator 444, and outputs to probe 446 at the load 448.

The input frequency of this example is from 10 MHz to 50 MHz and the parametric amplifier is pumped at 2.5 GHz with a power of 26 dBm, which upconverts the input to 2.45 to 2.49 GHz for the lower sideband and 2.51 to 2.55 GHz for the upper sideband. It should be appreciated that the frequency ranges and component selections are described herein by way of example and not limitation, as the techniques and circuits described may be applied to different frequency bands, and adapted for a wide range of application scenarios. In at least one embodiment, multiple varactor diode bridges, such as from the GCS 1 um InGaAs HBT D5 process, are placed in parallel to yield a 10 pF mean capacitance. The varactor diodes can be biased with a high value resistor, on the order of Mega Ohms, in practice to avoid the difficulty of needing a large value RF choke at this low frequency. The upconverted idler signals at around 2.5 GHz are amplified and then down converted with the same pump to avoid contamination of the LO phase noise.

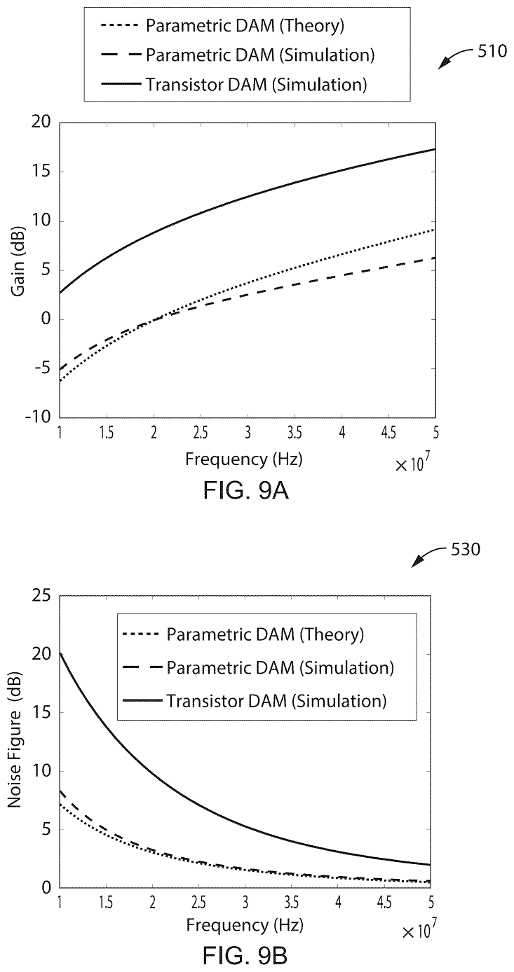

FIG. 9A and FIG. 9B illustrate example results 510, 530 of Gain and Noise from the circuit in FIG. 8 and compare results between parametric DAM theory, simulation, and a transistor DAM simulation.

Thus, the figures provide simulated gain of the entire system, excluding the gain of the idler amplifier as seen in FIG. 9A and the simulated noise figure is plotted in FIG. 9B, compared against the analytical results given by Eq. (18) and Eq. (25) and simulation results with the transistor DAM technique. The comparison between the theory and the circuit simulations agree very well in both gain and noise figure predictions and the slight deviation in gain for higher frequency is due to the bandpass behavior of the pump/idler port. Circuit simulations demonstrate that a positive transducer gain and a noise figure of less than 3 dB are achieved with the parametric DAM approach when the input frequency is greater than 20 MHz. The operational frequency band is more than one octave from 20 MHz to 42.5 MHz (ka=½ at 42.5 MHz). Comparing the simulation results with transistor DAM, it is seen that parametric DAM offers a lower gain, but it achieves a much lower noise figure through the entire frequency range with about 1.5 dB noise figure at 30 MHz versus 5 dB for transistor DAM.

With improved varactor technology, such as having a larger capacitance variation range and a higher cutoff frequency offered by the selected diodes (e.g., M/Acom off-the-shelf diodes (300 GHz cut-off frequency) or the BC diodes in Teledyne's 0.13 um InP HBT process (5 THz cutoff frequency)); it would be expected that the entire HF band from 3 MHz to 30 MHz can be covered with a noise figure of lower than 3 dB. One additional benefit of using the InP HBT diodes is that the capacitance tuning can be performed with a very small voltage, which is for example −0.5v-to-0.2v versus 0v-to-8v in the GCS diodes. This would result in a 20 dB drop in pump power consumption, and thus the parametric amplifier would consume a power of less than 10 dBm. It should be appreciated that using these techniques in a three dimensional design will allow the development parametric amplification circuits for ESA that operate with a radiation Q as close as possible to Chu's limit.

### 5. Experimental

To establish the standard of quantifying the noise performance of the receiver with ESA, Chu's ESA equivalent circuit model was used. In our preliminary study, the noise figure of the system was measured with ESA included, assuming the radiation resistance in Chu's model is the source resistance for noise figure calculation. Next, the parameters of the parametric amplifier were selected to match to the ESA so that a low noise figure can be achieved over a multioctave bandwidth. A complete theory for low noise matching with parametric amplifiers is derived and compared against that with active transistor amplifiers. It is concluded that the quality factor of the varactor diodes used in parametric amplifiers must be at least one order of magnitude higher than the radiation quality factor to gain the benefit of low noise figure.

### 6. General Scope of Embodiments

Embodiments of the technology of this disclosure may be described herein with reference to flowchart illustrations of methods and systems according to embodiments of the technology. Embodiments of the technology of this disclosure may also be described with reference to procedures, algorithms, steps, operations, formulae, or other computational depictions, which may be included within the flowchart illustrations or otherwise described herein. It will be appreciated that any of the foregoing may also be implemented as computer program instructions. In this regard, each block or step of a flowchart, and combinations of blocks (and/or steps) in a flowchart, as well as any procedure, algorithm, step, operation, formula, or computational depiction can be implemented by various means, such as hardware, firmware, and/or software including one or more computer program instructions embodied in computer-readable program code. As will be appreciated, any such computer program instructions may be executed by one or more computer processors, including without limitation a general purpose computer or special purpose computer, or other programmable processing apparatus to produce a machine, such that the computer program instructions which execute on the computer processor(s) or other programmable processing apparatus create means for implementing the function(s) specified.

Accordingly, blocks of the flowcharts, and procedures, algorithms, steps, operations, formulae, or computational depictions described herein support combinations of means for performing the specified function(s), combinations of steps for performing the specified function(s), and computer program instructions, such as embodied in computer-readable program code logic means, for performing the specified function(s). It will also be understood that each block of the flowchart illustrations, as well as any procedures, algorithms, steps, operations, formulae, or computational depictions and combinations thereof described herein, can be implemented by special purpose hardware-based computer systems which perform the specified function(s) or step(s), or combinations of special purpose hardware and computer-readable program code.

Furthermore, these computer program instructions, such as embodied in computer-readable program code, may also be stored in one or more computer-readable memory or memory devices that can direct a computer processor or other programmable processing apparatus to function in a particular manner, such that the instructions stored in the computer-readable memory or memory devices produce an article of manufacture including instruction means which implement the function specified in the block(s) of the flowchart(s). The computer program instructions may also be executed by a computer processor or other programmable processing apparatus to cause a series of operational steps to be performed on the computer processor or other programmable processing apparatus to produce a computer-implemented process such that the instructions which execute on the computer processor or other programmable processing apparatus provide steps for implementing the functions specified in the block(s) of the flowchart(s), procedure(s) algorithm(s), step(s), operation(s), formula (e), or computational depiction(s).

It will further be appreciated that the terms “programming” or “program executable” as used herein refer to one or more instructions that can be executed by one or more computer processors to perform one or more functions as described herein. The instructions can be embodied in software, in firmware, or in a combination of software and firmware. The instructions can be stored local to the device in non-transitory media, or can be stored remotely such as on a server, or all or a portion of the instructions can be stored locally and remotely. Instructions stored remotely can be downloaded (pushed) to the device by user initiation, or automatically based on one or more factors.

It will further be appreciated that as used herein, the terms controller, microcontroller, processor, microprocessor, hardware processor, computer processor, central processing unit (CPU), and computer are used synonymously to denote a device capable of executing the instructions and communicating with input/output interfaces and/or peripheral devices, and that the terms controller, microcontroller, processor, microprocessor, hardware processor, computer processor, CPU, and computer are intended to encompass single or multiple devices, single core and multicore devices, and variations thereof.

From the description herein, it will be appreciated that the present disclosure encompasses multiple implementations of the technology which include, but are not limited to, the following:

A parametric amplifier apparatus for sensitive reception using direct active matching (DAM) from an electrically small antenna (ESA), comprising: (a) a balanced varactor diode bridge configured for receiving radio frequency (RF) input from ESA inputs across a first set of inputs of said varactor diode bridge; (b) a pump comprising a pump source and source resistance, as shunted by an inductance, coupled across a second set of inputs of said varactor diode bridge; (c) wherein idler signals are extracted at a port on the pump and are separated from the pump by a circulator or a diplexer or a coupler and directed to a low noise amplifier (LNA) which amplifies the RF signal as a parametric amplifier output; and (d) wherein said balanced diode bridge isolates the signal path from the pump and idler paths, whereby the ESA is affected only by the varactor diode capacitance and resistance.

A parametric amplifier apparatus for sensitive reception using direct active matching (DAM) from an electrically small antenna (ESA), comprising: (a) a balanced varactor diode bridge configured receiving radio frequency (RF) input from ESA inputs across a first set of inputs of said varactor diode bridge; (b) a pump comprising a pump source and source resistance, as shunted by an inductance, coupled across a second set of inputs of said varactor diode bridge; (c) wherein the pump is configured to operate at a frequency that is sufficiently high in relation to the received signal, whereby the two idler sidebands fall within the bandwidth of the resonance of the pump loop; (d) wherein idler signals are extracted at a port on the pump and are separated from the pump by a circulator or a diplexer or a coupler and directed to a low noise amplifier (LNA) which amplifies the RF signal as a parametric amplifier output; (e) wherein symmetry in the balanced structure separates the pump signal from the antenna input and avoids the contamination of pump noise to the RF input from the antenna; (f) wherein said balanced diode bridge isolates the signal path from the pump and idler paths, whereby the ESA is affected only by the varactor diode capacitance and resistance; and (g) wherein having an isolated signal path in said balanced varactor diode bridge increases signal to noise performance of the parametric amplifier apparatus as any matching inductors or filters along the signal path would increase RF noise; and (h) wherein said parametric amplifier apparatus applies active and time-varying matching to enable broadband, low noise amplifier operation.

A parametric amplifier apparatus for sensitive reception using direct active matching (DAM) from an electrically small antenna (ESA), comprising: (a) a balanced varactor diode bridge configured for receiving radio frequency (RF) input from ESA inputs across a first set of inputs of said varactor diode bridge; (b) wherein said connection to said ESA does not require being conditioned through impedance matching or a transformation circuit; (c) a pump comprising a pump source and source resistance, as shunted by an inductance, coupled across a second set of inputs of said varactor diode bridge; (d) wherein said pump is configured for operating at a pump frequency chosen to be at least 10 times higher than the maximum frequency of the signal to be received; (e) wherein idler signals are extracted at a port on the pump and are separated from the pump by a circulator or a diplexer or a coupler and directed to a low noise amplifier (LNA) which amplifies the RF signal as a parametric amplifier output; and (f) wherein said balanced diode bridge isolates the signal path from the pump and idler paths, whereby the ESA is affected only by the varactor diode capacitance and resistance.

A direct active matching (DAM) method for receiver systems with electrically small antennas that achieves low noise performance over a broad bandwidth, wherein the DAM optimizes the signal to noise ratio of the receiver with the antenna rather than a conventional conjugate impedance match between the antenna and the receiver.

A parametric amplifier with a balanced architecture with antenna inputs and pump inputs connected to the four corners of a bridge of varactors.

The apparatus or method of any preceding implementation, wherein symmetry in the balanced structure separates the pump signal from the antenna input and avoids the contamination of pump noise to the RF input from the antenna.

The apparatus or method of any preceding implementation, further comprising a demodulator wherein the demodulator down converts the parametric amplifier output with the same pump applied to a local oscillator (LO) so that the phase noise of the LO/Pump is cancelled.

The apparatus or method of any preceding implementation, wherein the pump is configured to operate at a frequency that is sufficiently high in relation to the received signal, whereby the two idler sidebands fall within the bandwidth of the resonance of the pump loop.

The apparatus or method of any preceding implementation, wherein having an isolated signal path in said balanced varactor diode bridge increases signal to noise performance of the parametric amplifier apparatus as any matching inductors or filters along the signal path would increase RF noise.

The apparatus or method of any preceding implementation, whereby isolating the signal path in said balanced varactor diode bridge differs from amplifier circuits relying on a resonant matching network and diplexers to separate the different tones of signal, idler and pump.

The apparatus or method of any preceding implementation, further comprising matching inductors and impedance transformation circuits coupled at the pump and idler port toward increasing energy delivery efficiency, with minimal noise performance impact as the signal has already been amplified at the idler outputs.

The apparatus or method of any preceding implementation, wherein said parametric amplifier apparatus applies active and time-varying matching to enable broadband, low noise amplifier operation.

The apparatus or method of any preceding implementation, wherein said apparatus utilizes parametric amplification of nonlinear electron spin precessions in ferrite to allow detection of weak magnetic fields with an ESA, or small form factor sensor, over broad bands while subject to near negligible frequency dependence.

The apparatus or method of any preceding implementation, wherein said apparatus can be configured to provide broadband low noise performance at frequency ranges selected from the group of frequency ranges consisting of High Frequency (HF), Very High Frequency (VHF), and Ultra High Frequency (UHF) bands.

The apparatus or method of any preceding implementation, wherein said DAM apparatus is directed toward optimizing receiver noise and/or bandwidth performance by incorporating ESA equivalence into the circuit and analyzing the noise figure from said inputs from a dipole antenna to the output of the low noise amplifier (LNA) and thus considering radiation resistance of the dipole antenna as the source resistance for noise figure determinations.

The apparatus or method of any preceding implementation, wherein direct active matching of electrically small dipoles with a parametric amplifier results in the best signal to noise ratio when capacitance of the dipole is approximately equal to capacitance of the parametric amplifier.

The apparatus or method of any preceding implementation, wherein matching is based on inductor less, low loss capacitive matching to the antenna with parametric amplifier.

The apparatus or method of any preceding implementation, wherein symmetry in the balanced structure separates the pump signal from the antenna input and avoids the contamination of pump noise to the RF input from the antenna.

The apparatus or method of any preceding implementation, further comprising a demodulator wherein the demodulator down converts the parametric amplifier output with the same pump applied to a local oscillator (LO) so that the phase noise of the LO/Pump is cancelled.

As used herein, the term “implementation” is intended to include, without limitation, embodiments, examples, or other forms of practicing the technology described herein.

As used herein, the singular terms “a,” “an,” and “the” may include plural referents unless the context clearly dictates otherwise. Reference to an object in the singular is not intended to mean “one and only one” unless explicitly so stated, but rather “one or more.”

Phrasing constructs, such as “A, B and/or C”, within the present disclosure describe where either A, B, or C can be present, or any combination of items A, B and C. Phrasing constructs indicating, such as “at least one of” followed by listing a group of elements, indicates that at least one of these groups of elements is present, which includes any possible combination of the listed elements as applicable.

References in this disclosure referring to “an embodiment”, “at least one embodiment” or similar embodiment wording indicates that a particular feature, structure, or characteristic described in connection with a described embodiment is included in at least one embodiment of the present disclosure. Thus, these various embodiment phrases are not necessarily all referring to the same embodiment, or to a specific embodiment which differs from all the other embodiments being described. The embodiment phrasing should be construed to mean that the particular features, structures, or characteristics of a given embodiment may be combined in any suitable manner in one or more embodiments of the disclosed apparatus, system, or method.

As used herein, the term “set” refers to a collection of one or more objects. Thus, for example, a set of objects can include a single object or multiple objects.

Relational terms such as first and second, top and bottom, upper and lower, left and right, and the like, may be used solely to distinguish one entity or action from another entity or action without necessarily requiring or implying any actual such relationship or order between such entities or actions.

The terms “comprises,” “comprising,” “has”, “having,” “includes”, “including,” “contains”, “containing” or any other variation thereof, are intended to cover a non-exclusive inclusion, such that a process, method, article, apparatus, or system, that comprises, has, includes, or contains a list of elements does not include only those elements but may include other elements not expressly listed or inherent to such process, method, article, apparatus, or system. An element proceeded by “comprises . . . a”, “has a”, “includes . . . a”, “contains . . . a” does not, without more constraints, preclude the existence of additional identical elements in the process, method, article, apparatus, or system, that comprises, has, includes, contains the element.

As used herein, the terms “approximately”, “approximate”, “substantially”, “substantial”, “essentially”, and “about”, or any other version thereof, are used to describe and account for small variations. When used in conjunction with an event or circumstance, the terms can refer to instances in which the event or circumstance occurs precisely as well as instances in which the event or circumstance occurs to a close approximation. When used in conjunction with a numerical value, the terms can refer to a range of variation of less than or equal to ±10% of that numerical value, such as less than or equal to ±5%, less than or equal to ±4%, less than or equal to ±3%, less than or equal to ±2%, less than or equal to ±1%, less than or equal to ±0.5%, less than or equal to ±0.1%, or less than or equal to ±0.05%. For example, “substantially” aligned can refer to a range of angular variation of less than or equal to ±10°, such as less than or equal to ±5°, less than or equal to ±4°, less than or equal to ±3°, less than or equal to ±2°, less than or equal to ±1°, less than or equal to ±0.5°, less than or equal to ±0.1°, or less than or equal to ±0.05°.

Additionally, amounts, ratios, and other numerical values may sometimes be presented herein in a range format. It is to be understood that such range format is used for convenience and brevity and should be understood flexibly to include numerical values explicitly specified as limits of a range, but also to include all individual numerical values or sub-ranges encompassed within that range as if each numerical value and sub-range is explicitly specified. For example, a ratio in the range of about 1 to about 200 should be understood to include the explicitly recited limits of about 1 and about 200, but also to include individual ratios such as about 2, about 3, and about 4, and sub-ranges such as about 10 to about 50, about 20 to about 100, and so forth.

The term “coupled” as used herein is defined as connected, although not necessarily directly and not necessarily mechanically. A device or structure that is “configured” in a certain way is configured in at least that way, but may also be configured in ways that are not listed.

Benefits, advantages, solutions to problems, and any element(s) that may cause any benefit, advantage, or solution to occur or become more pronounced are not to be construed as a critical, required, or essential feature or element of the technology described herein or any or all the claims.

In addition, in the foregoing disclosure various features may be grouped together in various embodiments for the purpose of streamlining the disclosure. This method of disclosure is not to be interpreted as reflecting an intention that the claimed embodiments require more features than are expressly recited in each claim. Inventive subject matter can lie in less than all features of a single disclosed embodiment.

The abstract of the disclosure is provided to allow the reader to quickly ascertain the nature of the technical disclosure. It is submitted with the understanding that it will not be used to interpret or limit the scope or meaning of the claims.

It will be appreciated that the practice of some jurisdictions may require deletion of one or more portions of the disclosure after the application is filed. Accordingly, the reader should consult the application as filed for the original content of the disclosure. Any deletion of content of the disclosure should not be construed as a disclaimer, forfeiture, or dedication to the public of any subject matter of the application as originally filed.

All text in a drawing figure is hereby incorporated into the disclosure and is to be treated as part of the written description of the drawing figure.

The following claims are hereby incorporated into the disclosure, with each claim standing on its own as a separately claimed subject matter.

Although the description herein contains many details, these should not be construed as limiting the scope of the disclosure, but as merely providing illustrations of some of the presently preferred embodiments. Therefore, it will be appreciated that the scope of the disclosure fully encompasses other embodiments which may become obvious to those skilled in the art.

All structural and functional equivalents to the elements of the disclosed embodiments that are known to those of ordinary skill in the art are expressly incorporated herein by reference and are intended to be encompassed by the present claims. Furthermore, no element, component, or method step in the present disclosure is intended to be dedicated to the public regardless of whether the element, component, or method step is explicitly recited in the claims. No claim element herein is to be construed as a “means plus function” element unless the element is expressly recited using the phrase “means for”. No claim element herein is to be construed as a “step plus function” element unless the element is expressly recited using the phrase “step for”.

What is claimed is:

1. A parametric amplifier apparatus for sensitive reception using direct active matching (DAM) from an electrically small antenna (ESA), comprising:
a balanced varactor diode bridge configured for receiving radio frequency (RF) input from ESA inputs across a first set of inputs of said varactor diode bridge;
a pump comprising a pump source and source resistance, as shunted by an inductance, coupled across a second set of inputs of said varactor diode bridge;
wherein idler signals are extracted at a port on the pump and are separated from the pump by a circulator or a diplexer or a coupler and directed to a low noise amplifier (LNA) which amplifies the RF signal as a parametric amplifier output; and
wherein said balanced diode bridge isolates the signal path from the pump and idler paths, whereby the ESA is affected only by the varactor diode capacitance and resistance.

2. The apparatus of claim 1, wherein symmetry in the balanced structure separates the pump signal from the antenna input and avoids the contamination of pump noise to the RF input from the antenna.

3. The apparatus of claim 1, further comprising a demodulator wherein the demodulator down converts the parametric amplifier output with the same pump applied to a local oscillator (LO) so that the phase noise of the LO/Pump is cancelled.

4. The apparatus of claim 1, wherein the pump is configured to operate at a frequency that is sufficiently high in relation to the received signal, whereby the two idler sidebands fall within the bandwidth of the resonance of the pump loop.

5. The apparatus of claim 1, wherein having an isolated signal path in said balanced varactor diode bridge increases signal to noise performance of the parametric amplifier apparatus as any matching inductors or filters along the signal path would increase RF noise.

6. The apparatus of claim 5, whereby isolating the signal path in said balanced varactor diode bridge differs from amplifier circuits relying on a resonant matching network and diplexers to separate the different tones of signal, idler and pump.

7. The apparatus of claim 6, further comprising matching inductors and impedance transformation circuits coupled at the pump and idler port toward increasing energy delivery efficiency, with minimal noise performance impact as the signal has already been amplified at the idler outputs.

8. The apparatus of claim 1, wherein said parametric amplifier apparatus applies active and time-varying matching to enable broadband, low noise amplifier operation.

9. The apparatus of claim 1, wherein said apparatus utilizes parametric amplification of nonlinear electron spin precessions in ferrite to allow detection of weak magnetic fields with an ESA, or small form factor sensor, over broad bands while subject to near negligible frequency dependence.

10. The apparatus of claim 1, wherein said apparatus can be configured to provide broadband low noise performance at frequency ranges selected from the group of frequency ranges consisting of High Frequency (HF), Very High Frequency (VHF), and Ultra High Frequency (UHF) bands.

11. The apparatus of claim 1, wherein said DAM apparatus is directed toward optimizing receiver noise and/or bandwidth performance by incorporating ESA equivalence into the circuit and analyzing the noise figure from said inputs from a dipole antenna to the output of the low noise amplifier (LNA) and thus considering radiation resistance of the dipole antenna as the source resistance for noise figure determinations.

12. A parametric amplifier apparatus for sensitive reception using direct active matching (DAM) from an electrically small antenna (ESA), comprising:
a balanced varactor diode bridge configured receiving radio frequency (RF) input from ESA inputs across a first set of inputs of said varactor diode bridge;
a pump comprising a pump source and source resistance, as shunted by an inductance, coupled across a second set of inputs of said varactor diode bridge;
wherein the pump is configured to operate at a frequency that is sufficiently high in relation to the received signal, whereby the two idler sidebands fall within the bandwidth of the resonance of the pump loop;
wherein idler signals are extracted at a port on the pump and are separated from the pump by a circulator or a diplexer or a coupler and directed to a low noise amplifier (LNA) which amplifies the RF signal as a parametric amplifier output;
wherein symmetry in the balanced structure separates the pump signal from the antenna input and avoids the contamination of pump noise to the RF input from the antenna;
wherein said balanced diode bridge isolates the signal path from the pump and idler paths, whereby the ESA is affected only by the varactor diode capacitance and resistance; and
wherein having an isolated signal path in said balanced varactor diode bridge increases signal to noise performance of the parametric amplifier apparatus as any matching inductors or filters along the signal path would increase RF noise; and
wherein said parametric amplifier apparatus applies active and time-varying matching to enable broadband, low noise amplifier operation.

13. The apparatus of claim 12, further comprising a demodulator wherein the demodulator down converts the parametric amplifier output with the same pump applied to a local oscillator (LO) so that the phase noise of the LO/Pump is cancelled.

14. The apparatus of claim 12, whereby isolated the signal path in said balanced varactor diode bridge differs from amplifier circuits relying on a resonant matching network and diplexers to separate the different tones of signal, idler and pump.

15. The apparatus of claim 12, further comprising matching inductors and impedance transformation circuits coupled at the pump and idler port toward increasing energy delivery efficiency, with minimal noise performance impact as the signal has already been amplified at the idler outputs.

16. The apparatus of claim 12 wherein said apparatus utilizes parametric amplification of nonlinear electron spin precessions in ferrite to allow detection of weak magnetic fields with an ESA, or small form factor sensor, over broad bands while subject to near negligible frequency dependence.

17. The apparatus of claim 12, wherein said apparatus can be configured to provide broadband low noise performance at frequency ranges selected from the group of frequency ranges consisting of High Frequency (HF), Very High Frequency (VHF), and Ultra High Frequency (UHF) bands.

18. The apparatus of claim 12, wherein said DAM apparatus is directed toward optimizing receiver noise and/or bandwidth performance by incorporating ESA equivalence into the circuit and analyzing the noise figure from said inputs from a dipole antenna to the output of the low noise amplifier (LNA) and thus considering radiation resistance of the dipole antenna as the source resistance for noise figure determinations.

19. A parametric amplifier apparatus for sensitive reception using direct active matching (DAM) from an electrically small antenna (ESA), comprising:
a balanced varactor diode bridge configured for receiving radio frequency (RF) input from ESA inputs across a first set of inputs of said varactor diode bridge;
wherein said connection to said ESA does not require being conditioned through impedance matching or a transformation circuit;
a pump comprising a pump source and source resistance, as shunted by an inductance, coupled across a second set of inputs of said varactor diode bridge;
wherein said pump is configured for operating at a pump frequency chosen to be at least 10 times higher than the maximum frequency of the signal to be received;
wherein idler signals are extracted at a port on the pump and are separated from the pump by a circulator or a diplexer or a coupler and directed to a low noise amplifier (LNA) which amplifies the RF signal as a parametric amplifier output; and
wherein said balanced diode bridge isolates the signal path from the pump and idler paths, whereby the ESA is affected only by the varactor diode capacitance and resistance.

20. The apparatus of claim 19, wherein said parametric amplifier apparatus applies active and time-varying matching to enable broadband, low noise amplifier operation.
